(19) United States
(12) Patent Application Publication
(10) Pub. No.: US 2009/0200924 A1
(43) Pub. Date: Aug. 13, 2009

(54) Oganic EL display device and manufacturing method thereof

(75) Inventors: Eiji Matsuzaki, Yokohama (JP); Yoshinori Ishii, Chiba (JP); Satoru Kase, Mobara (JP)

Correspondence Address: Stanley P. Fisher;Reed Smith LLP, 3110 Fairview Park Drive, Suite 1400, Falls Church, VA, 22042-4503, US

(73) Assignee: Hitachi Displays, Ltd.

(21) Appl. No.: 12/289,820

(22) Filed: Nov. 5, 2008

(30) Foreign Application Priority Data
Nov. 6, 2007 (JP) 2007-288925

(51) Int. Cl. H01J 1/63; H01J 9/26

(52) U.S. Cl. 313/504; 445/25

(57) ABSTRACT

A sealing method of an organic EL display device which can effectively prevent the organic EL display device from being influenced by moisture and can suppress the manufacturing cost of the organic EL display device is provided. An organic EL element is covered with a resin sheet. The resin sheet is adhered to a sealing substrate and an element substrate on which organic EL elements are formed by lamination. At a peripheral portion of the organic EL display device, between the element substrate and the sealing substrate, an organic seal is filled to a side portion of the resin sheet using an under-filling method, and the organic seal is cured by radiating ultraviolet rays. Due to such constitution, it is possible to realize the highly reliable sealing of the organic EL display devices at a low cost.

### CROSS-REFERENCE TO RELATED APPLICATIONS

The present application claims priority from Japanese Application JP 2007-288925 filed on Nov. 6, 2007, the content of which is hereby incorporated by reference into this application.

### BACKGROUND OF THE INVENTION

1. Field of the Invention

The present invention relates to an organic EL (electroluminescence) display device, and more particularly to a highly reliable top-emission-type organic EL display device which suppresses the generation of dark spots attributed to moisture.

2. Background Art

In an organic EL display device, an organic EL layer is sandwiched between a pixel electrode (lower electrode) and an upper electrode, a fixed voltage is applied to the upper electrode, and emission of light from the organic EL layer is controlled by applying a data signal voltage to the lower electrode thus forming an image. The data signal voltage is supplied to the lower electrode via a thin film transistor (TFT).

An organic EL display device is classified into a bottom-emission-type organic EL display device in which light emitted from organic EL layers is taken out in the direction of a glass substrate on which the organic EL layers and the like are formed and a top-emission-type organic EL display device in which light emitted from organic EL layers is taken out in the direction opposite to a glass substrate on which the organic EL layers and the like are formed. The top-emission-type organic EL display device has an advantage that the respective organic EL layers can ensure a large light emission area thus increasing the brightness of a display.

When moisture is present in an organic EL material used in an organic EL display device, the light emission characteristic is deteriorated and hence, when the organic EL display device is operated for a long time, portions of the organic EL material which are deteriorated with moisture do not emit light. These portions appear as dark spots on a display region. The dark spots grow with time and become a defect of an image.

To prevent the generation or the growth of the dark spots, it is necessary to prevent the intrusion of moisture into the inside of the organic EL display device or to remove the intruded moisture from the organic EL display device. Accordingly, an element substrate on which an organic EL layer is formed is sealed by a sealing substrate thus preventing the intrusion of moisture into the inside of the organic EL display device from the outside. On the other hand, to remove moisture intruded into the inside of the organic EL display device, a desiccant is arranged in the inside of the organic EL display device. This organic EL display device is referred to as a hollow-sealed-type organic EL display device.

The hollow-sealed-type organic EL display device has drawbacks such as difficulty in adjusting a gap between the element substrate and the sealing substrate, difficulty in adjusting pressure in the sealed inside, contamination of the organic EL material by a gas discharged from a sealing agent at the time of performing the sealing operation using a sealing agent or a low throughput.

To cope with such drawbacks attributed to the hollow sealed structure, there has been known a technique which sandwiches a resin sheet having a fixed film thickness between an element substrate and a sealing substrate thus protecting an organic EL material from moisture using such a resin sheet. This technique is referred to as solid sealing.

JP-2004-139977 (patent document 1) discloses an example of solid sealing, and FIG. 5(A) to FIG. 5(D) show the constitution of such an example disclosed in patent document 1. In FIG. 5(A) to FIG. 5(D), a photo curing resin 102 which is formed on a light transmitting film 101 is laminated to an element substrate 10 on which organic EL elements 103 are formed using a compression bonding roller 105 which is heated at a temperature of 80° C. Next, ultraviolet rays are radiated to the photo curing resin 102 so as to cure the photo curing resin 102 and, thereafter, the light transmitting film 101 is peeled off thus acquiring an organic EL display device sealed with the photo curing resin. Further, when necessary, the organic EL elements are covered with a silicon nitride film.

An article written by Shinya Saeki in Nikkei Electronics issued on Sep. 10, 2007, No. 960 pp 10-11 (non-patent document 1) discloses a following technique for sealing an organic EL display device. That is, as shown in FIG. 6(A) to FIG. 6(E), resin films 107 are laminated to portions of a sealing substrate 40 corresponding to organic EL elements 103 and, thereafter, a sealing agent 108 is drawn around the resin film 107. The sealing substrate 40 on which the resin films 107 are formed using the sealing agents 108 and an element substrate 10 on which the organic EL elements 103 are formed are laminated to each other. Next, ultraviolet rays are radiated from the sealing substrate 40 so as to perform heat treatment at a temperature which falls within a range from 80° C. to 100° C. Due to such heat treatment, the sealing agents 108 are cured and, at the same time, the resin film 107 which obtains fluidity spreads in a space formed by the sealing substrate 40, the element substrate 10 and the sealing agent 108 and is filled in the space. Finally, the sealed laminated structure is divided into individual organic EL display panels as products.

### SUMMARY OF THE INVENTION

The technique disclosed in “patent document 1” uses an organic material as the sealing material and hence, the sealing material has water permeability. Accordingly, compared to a case in which sealing is performed using a glass material, the technique which performs sealing using the organic material exhibits poor sealing ability. Further, moisture is liable to stay in a gap between the organic EL element and a photo curing resin. Even when the organic EL layer is covered with a silicon nitride film, it is difficult to obtain a defect-free film and hence, it is difficult for the technique disclosed in patent document 1 to acquire sealing ability substantially comparable to sealing ability when the sealing is performed using the glass substrate.

With respect to the technique disclosed in “non-patent document 1”, it is necessary to take a balance in height between the resin film and the sealing material. This is because when the balance in height collapses, a lifetime of the organic EL display device is deteriorated. Further, although the resin film exhibits fluidity and spreads in the heating step after sealing, pressure inside the organic EL display device is increased due to such spreading of the resin film and hence, a leak path leading to the outside is formed thus giving rise to possibility that a lifetime of the organic EL display device is deteriorated. Further, due to the influence of a gas discharged exerted on the resin sheet when the sealing agent is cured, there exists possibility that sealing ability is lowered. In the technique disclosed in “non-patent document 1”, a gap defined between the sealing substrate and the element substrate is filled with a resin and hence, this resin-filled sealing structure exhibits a large mechanical strength compared to the above-mentioned hollow sealing structure. However, the resin-filled sealing structure and the hollow sealing structure are substantially equal to each other with respect to the sealing step and hence, there also arises a drawback that a throughput is low.

The present invention has been made to overcome the above-mentioned drawbacks, and it is an object of the present invention to realize a solid-sealing-type organic EL display device which exhibits highly reliable sealing and a high throughput.

According to a typical constitution for overcoming the above-mentioned drawbacks, the present invention provides the constitution in which an element substrate is sealed by a resin sheet and a sealing substrate, and a space which is formed around a side surface of the resin sheet and between the element substrate and the sealing substrate is filled with an organic sealing material. To explain specific constitutions of the present invention, they are as follows.

(1) According to a first aspect of the present invention, there is provided an organic EL display device which includes: an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and a sealing substrate which seals the display region, wherein a resin sheet is sandwiched between the element substrate and the sealing substrate, and a space which is formed around a side surface of the resin sheet and between the element substrate and the sealing substrate is filled with an organic seal.

(2) In the organic EL display device having the constitution (1), the resin sheet is laminated to the sealing substrate, and the resin sheet is also laminated to the upper electrodes of the element substrate.

(3) In the organic EL display device having the constitution (1), the organic seal is cured by ultraviolet rays.

(4) In the organic EL display device having the constitution (1), a protective film is formed on the upper electrodes.

(5) In the organic EL display device having the constitution (4), the protective film is an inorganic film and contains any one of SiNx, SiOx and SiNxOy.

(6) In the organic EL display device having the constitution (4), the protective film is formed of a plurality of layers, and at least one layer out of the plurality of layers contains any one of SiNx, SiOx and SiNxOy.

(7) According to a second aspect of the present invention, there is provided an organic EL display device which includes: an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and a sealing substrate which seals the display region, wherein a resin sheet is sandwiched between the element substrate and the sealing substrate, an inorganic seal is formed on a side surface of the resin sheet and between the element substrate and the sealing substrate, and an organic seal is formed outside the inorganic seal and between the element substrate and the sealing substrate.

(8) In the organic EL display device having the constitution (7), the inorganic seal contains any one of silicon oxide, silicon nitride, titanium oxide, aluminum oxide, zirconium oxide, and magnesium oxide.

(9) In the organic EL display device having the constitution (7), a protective film is formed on the upper electrodes.

(10) In the organic EL display device having the constitution (7), the protective film is an inorganic film and contains any one of SiNx, SiOx and SiNxOy.

(11) In the organic EL display device having the constitution (7), the protective film is formed of a plurality of layers, and at least one layer out of the plurality of layers contains any one of SiNx, SiOx and SiNxOy.

(12) According to a third aspect of the present invention, there is provided a manufacturing method of an organic EL display device which includes an element substrate having a display region on which pixels each of which has an upper electrode, a lower electrode, and an organic EL layer sandwiched between the upper electrode and the lower electrode are formed in a matrix array and a terminal portion which supplies an electric current and a signal to the display region, a sealing substrate which seals the display region, and a resin sheet which is sandwiched between the element substrate and the sealing substrate, wherein the manufacturing method of an organic EL display device includes the steps of: adhering the resin sheet to a predetermined position of the sealing substrate; adhering the resin sheet to the element substrate; and filling an organic seal in a space which is formed around a side surface of the resin sheet and between the element substrate and the sealing substrate.

(13) In the manufacturing method of the organic EL display device having the constitution (12), the sealing substrate and the resin sheet are adhered to each other by lamination, and the resin sheet and the element substrate are adhered to each other by lamination.

(14) In the manufacturing method of the organic EL display device having the constitution (12), the organic seal is filled in a space formed between the element substrate and the sealing substrate by an under-filling method.

(15) According to a fourth aspect of the present invention, there is provided a manufacturing method of an organic EL display device which includes an element substrate having a display region on which pixels each of which has an upper electrode, a lower electrode, and an organic EL layer sandwiched between the upper electrode and the lower electrode are formed in a matrix array and a terminal portion which supplies an electric current and a signal to the display region, a sealing substrate which seals the display region, and a resin sheet which is sandwiched between the element substrate and the sealing substrate, wherein the manufacturing method of an organic EL display device includes the steps of: adhering a mother element substrate on which a plurality of regions each including the display region and the terminal portion is formed and a mother sealing substrate to which a plurality of resin sheets is adhered corresponding to the display regions to each other; separating a substrate formed by adhering the mother element substrate and the mother sealing substrate into individual organic EL display panels; and applying an organic seal to a side surface of the resin sheet between the element substrate and the sealing substrate of the separated organic EL display panel by coating.

(16) In the manufacturing method of an organic EL display device having the constitution (15), the organic seal is applied to the side surface by an under-filling method.

In the present invention, the organic EL layer is protected by the resin sheet and the organic seal in a duplicated manner and hence, a high moisture prevention effect can be obtained. Accordingly, it is possible to realize an organic EL display device having an excellent lifetime characteristic. Further, by arranging the inorganic seal between the resin sheet and the organic seal, a higher moisture prevention effect can be obtained. Further, by forming the protective film on the upper electrodes and by adhering the protective film and the resin sheet to each other, it is possible to further enhance the reliability of the organic EL display device on moisture prevention.

### BRIEF DESCRIPTION OF THE DRAWINGS

FIG. 1 is a cross-sectional view of a display region of an organic EL display device of an embodiment 1;

FIG. 2(A) to FIG. 2(F) are views showing manufacturing steps of the organic EL display device of the embodiment 1;

FIG. 3(A) to FIG. 3(F) are views showing manufacturing steps of an organic EL display device of an embodiment 2;

FIG. 4 is a cross-sectional view of a display region of an organic EL display device of an embodiment 3;

FIG. 5(A) to FIG. 5(D) are views showing manufacturing steps of a conventional organic EL display device; and

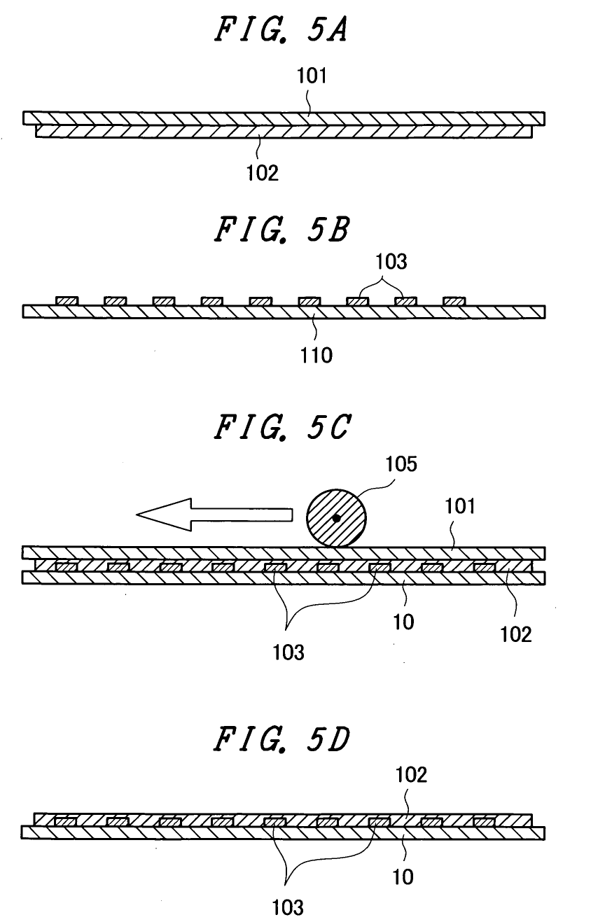

FIG. 6(A) to FIG. 6(E) are views showing manufacturing steps of another conventional organic EL display device.

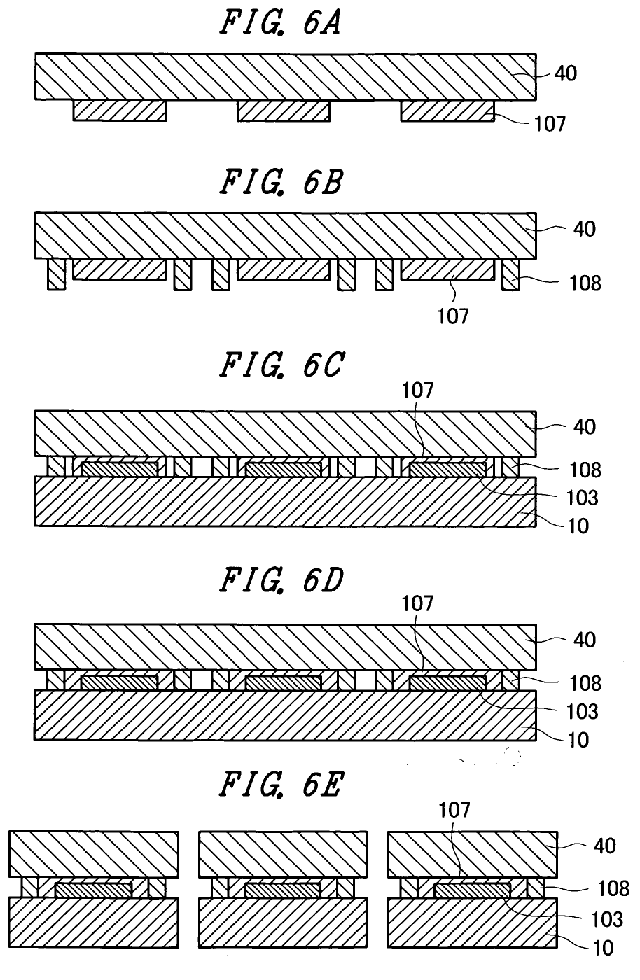

### DESCRIPTION OF THE PREFERRED EMBODIMENTS

Hereinafter, the present invention is explained in detail in conjunction with embodiments.

### Embodiment 1

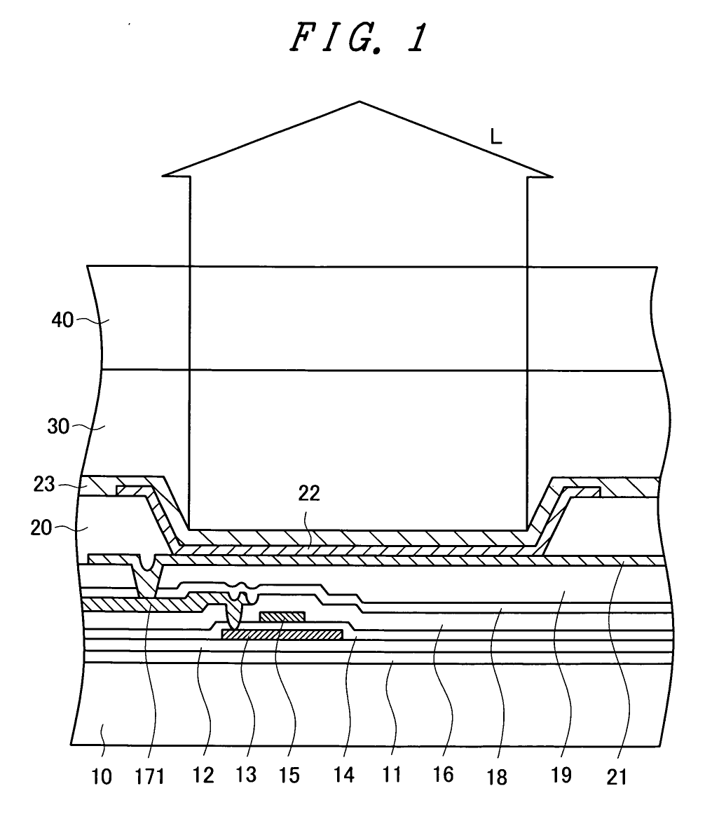

FIG. 1 is a cross-sectional view of a display region of a top-emission-type organic EL display device to which the present invention is applied. Although this embodiment is explained by taking the top-emission-type organic EL display device as an example, the present invention is also applicable to a bottom-emission type organic EL display device in the same manner. The top-emission-type organic EL display device can be classified into a top-anode-type organic EL display device in which an anode is arranged above an organic EL layer 22 and a top-cathode-type organic EL display device in which a cathode is arranged above an organic EL layer 22. Although FIG. 1 shows the top-anode type organic EL display device, the present invention is also applicable to the top-cathode type organic EL display device in the same manner.

As shown in FIG. 1, a first background film 11 made of SiN and a second background film 12 made of SiO₂ are formed on an element substrate 10. These background films 11, 12 are provided for preventing impurities from a glass substrate from contaminating a semiconductor layer 13. The semiconductor layer 13 is formed on the second background film 12. In forming the semiconductor layer 13, an a-Si film is firstly formed by a CVD method and, thereafter, the a-Si film is formed into a poly-Si film by radiating laser beams to the a-Si film.

A gate insulation film 14 made of SiO₂ is formed so as to cover the semiconductor layer 13. A gate electrode 15 is formed in a state that the gate electrode 15 faces the semiconductor layer 13 in an opposed manner with the gate insulation film 14 sandwiched therebetween. Using the gate electrode 15 as a mask, the semiconductor layer 13 is doped with impurities such as phosphorus or boron by ion implantation so as to make the semiconductor layer 13 conductive thus forming a source portion or a drain portion in the semiconductor layer 13.

An interlayer insulation film 16 made of SiO₂ is formed so as to cover the gate electrode 15. The interlayer insulation film 16 is provided for ensuring the insulation between gate lines and drain lines 171. The drain line 171 is formed on the interlayer insulation film 16. The drain line 171 is connected with the drain of the semiconductor layer 13 via a through hole formed in the interlayer insulation film 16 and the gate insulation film 14.

Thereafter, to protect a thin film transistor (TFT) formed in the above-mentioned manner, an inorganic passivation film 18 made of SiN is formed on the interlayer insulation film 16 by coating. An organic passivation film 19 is formed on the inorganic passivation film 18. The organic passivation film 19 plays a role of protecting the TFT more completely together with the inorganic passivation film 18. The organic passivation film 19 also plays a role of leveling a surface on which an organic EL layer 22 is formed. Accordingly, the organic passivation film 19 has a large thickness of 1 to 4 μm.

A reflection electrode 24 made of Al or Al alloy is formed on the organic passivation film 19. Since Al or Al alloy exhibits high reflectance, Al or Al alloy is preferably used as a material of the reflection electrode 24. The reflection electrode 24 is connected with the drain line 171 via a through hole formed in the organic passivation film 19 and the inorganic passivation film 18.

This embodiment provides the top-anode-type organic EL display device and hence, a lower electrode 21 of the organic EL layer 22 constitutes a cathode. Accordingly, the Al layer or Al alloy layer which is used for forming the reflection electrode 24 is also used for forming the lower electrode 21 of the organic EL layer 22. This is because Al or an Al alloy has a relatively small work function and hence, Al or Al alloy can function as a cathode.

The organic EL layer 22 is formed on the lower electrode 21. The organic EL layer 22 is constituted of an electron transport layer, a light emission layer and a hole transport layer which are laminated from below. Here, an electron injection layer may be interposed between the electron transport layer and the lower electrode 21. Further, a hole injection layer may be interposed between the hole transport layer and an upper electrode 23. The upper electrode 23 which constitutes an anode is formed on the organic EL layer 22. In this embodiment, the upper electrode 23 is made of IZO. The IZO film is formed over the whole display region by vapor deposition without using a mask. A thickness of the IZO film is set to approximately 30 nm for maintaining optical transmissivity. An ITO film may be used in place of the IZO film.

A material which can be used as an electron-transport-layer material is not specifically limited provided that the material exhibits electron transport property and can be easily formed into a charge-transfer complex by co-deposition with alkali metal and, for example, a metal complex such as tris (8-quinolinolato) aluminum, tris (4-methyl-8-quinolinolato) aluminum, bis (2-methyl-8-quinolinolato)-4-phenylphenolato-aluminum, bis [2-[2-hydroxyphenyl]benzooxazolato] zinc, 2-(4-biphenylyl)-5-(4-tert-butylphenyl)-1,3,4-oxadiazol, 1,3-bis[5-(p-tert-butylphenyl)-1,3,4-oxadiazol-2-yl] benzene or the like can be used.

A material which can be used as a light-emitting-layer material is not specifically limited provided that the material is made of a host material which has an electron-and-hole transporting ability, and a dopant which is added to the host material, emits a fluorescent light or a phosphorous light by re-coupling with the host material and forms a light emitting layer by co-vapor-deposition. For example, as the host material, a complex such as tris (8-quinolinolato) aluminum, bis(8-quinolinolato) magnesium, bis(benzo{f}-8-quinolinolato) zinc, bis (2-methyl-8-quinolinolato) aluminum oxide, tris (8-quinolinolato) indium, tris (5-methyl-8-quinolinolato) aluminum, 8-quinolinolato lithium, tris (5-chloro-8-quinolinolato) gallium, bis (5-chloro-8-quinolinolato) calcium, 5,7-dichloro-8-quinolinolato aluminum, tris (5,7-dibromo-8-hydroxyquinolinolato) aluminum, and poly [zinc(II)-bis(8-hydroxy-5-quinolinyl) methane], an anthracene derivative, a carbazole derivative or the like can be used.

Further, the dopant is a material which captures electrons and holes in a host material and emits light by re-coupling. For example, the red dopant may be formed of a pyran derivative, the green dopant may be formed of a coumarin derivative, and the blue dopant may be formed of a substance which emits fluorescent light such as an anthracene derivative or a substance which emits phosphorescence such as an iridium complex and a pyridinato derivative.

The hole transport layer may be made of tetraaryl benzidine compound (triphenyl diamine: TPD), aromatic tertiary amine, hydrazone derivative, carbazole derivative, triazole derivative, imidazole derivative, oxadiazole derivative having an amino group, polythiophene derivative, copper phthalocyanine derivative or the like, for example.

Here, to prevent the organic EL layer 22 from being broken at an end portion thereof due to a broken step, a bank 20 is formed between the pixels. The bank 20 may be formed of an organic material, or the bank 20 may be formed of an inorganic material such as SiN. In forming the bank 20 using the organic material, in general, an acrylic resin or a polyimide resin is used.

An auxiliary electrode may be formed on the upper electrode which is formed on the bank 20 for assisting the electrical conduction of the upper electrode. This is because when the resistance of the upper electrode is large, brightness irregularities may occur. Although the auxiliary electrode is not used in this embodiment, it is needless to say that the present invention is also applicable to an organic EL display device which uses the auxiliary electrode.

In FIG. 1, a resin sheet 30 is formed on the upper electrode. The resin sheet 30 is adhered to the upper electrode by a lamination method. A thickness of the resin sheet 30 is set to 10 μm, for example. The resin sheet 30 is made of an acrylic resin, for example. A sealing substrate 40 is formed on the resin sheet 30. The sealing substrate 40 and the resin sheet 30 are also adhered to each other by a lamination method.

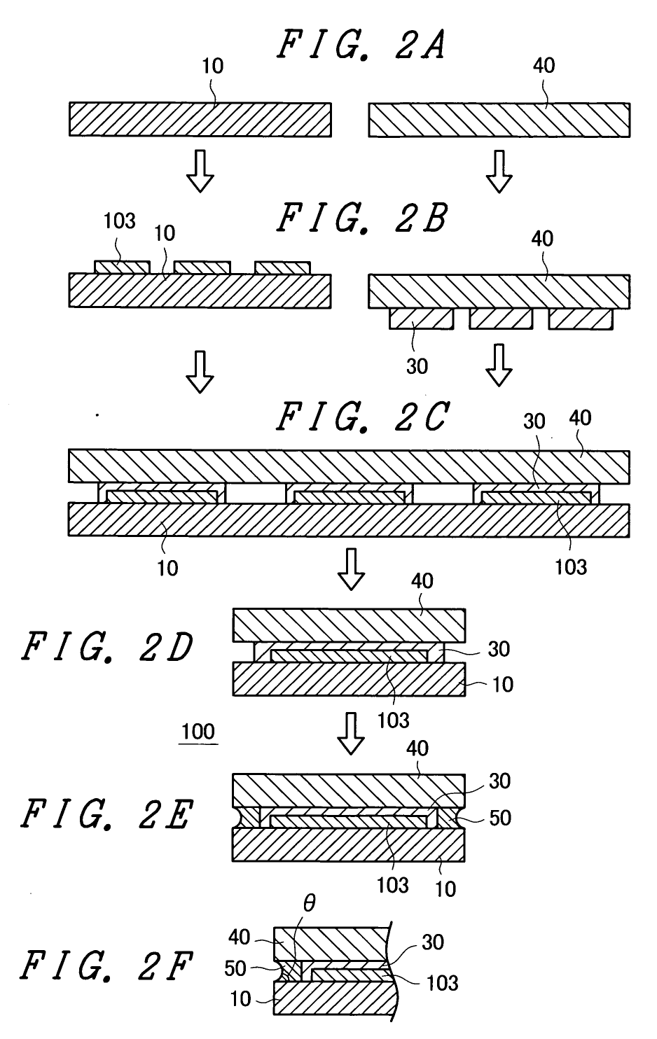

FIG. 2(A) to FIG. 2(F) are views showing manufacturing steps of the organic EL display device of the present invention. FIG. 2(A) shows an element substrate 10 made of glass. From this element substrate 10, a plurality of organic EL display panels for constituting a plurality of the organic EL display devices are formed. A plate thickness of the element substrate 10 is set to 0.5 mm, for example. FIG. 2(B) shows a state that organic EL elements 103 are formed on the element substrate 10. In this specification, the organic EL element 103 is a general term used to collectively indicate a display region which includes organic EL layers formed in a matrix array, TFTs, power source lines, video signal lines or the like for driving the organic EL layers 22. The element substrate 10 shown in FIG. 2(B) is a mother substrate on which a plurality of organic EL elements 103 is formed. The mother substrate is adhered to a mother substrate of the sealing substrate 40 and, thereafter, is separated into the plurality of organic EL display panels.

FIG. 2(A) shows the sealing substrate 40 for protecting the organic EL layer. The sealing substrate 40 is also a mother substrate having the substantially same size as the element substrate 10 shown in FIG. 2(A). The mother sealing substrate 40 is separated later into a plurality of sealing substrates 40 which constitutes the organic EL display panels. FIG. 2(B) shows a state that a resin sheet 30 is laminated to the sealing substrate 40. The resin sheet 30 is made of an acrylic resin. In this lamination step, in a reduced pressure atmosphere, the resin sheet 30 is heated to a temperature which falls within a range from 50° C. to 120° C. and pressure is applied to the resin sheet 30.

In FIG. 2(B), the resin sheets 30 are separated at this point of time. That is, it is preferable that the resin sheets 30 are not arranged on cutting-line portions of the mother substrate of the sealing substrate 40 along which the mother substrate is separated. Further, at this point of time, it is preferable that the resin sheets 30 are not arranged also on portions corresponding to the terminal portions formed on the element substrate.

However, the present invention is not limited to such a separation method. That is, the present invention can use a separation method described later in which the resin sheets 30 are not separated at a point time shown in FIG. 2(B) and are separated later. A size of the resin sheet 30 which is separated at this point of time is set larger than a size of the organic EL element 103 shown in FIG. 2(B). This is because a side portion of the organic EL element 103 can be also sealed sufficiently with the resin sheet 30.

FIG. 2(C) is a view showing a state in which the element substrate 10 on which a plurality of organic EL elements 103 is formed and the sealing substrate 40 on which the plurality of resin sheets 30 is formed are adhered to each other. The adhesion between the element substrate and the sealing substrate 40 is performed by laminating the resin sheet 30 to the element substrate. Lamination of the resin sheet 30 to the element substrate is performed such that, in a reduced pressure atmosphere, the sealing substrate 40 is pressed to the element substrate side in a state that the element substrate is heated to a temperature which falls within a range between 50° C. and 120° C. In FIG. 2(C), the plurality of organic EL display elements 103 is sealed by the resin sheets 30 and the sealing substrate 40 by lamination. Here, in an actual manufacturing operation, the resin sheets 30 are laminated to upper electrodes formed on the organic EL layers which are formed on the element substrate 10.

FIG. 2(D) shows one of the organic EL display panels formed by separating the laminated body of the element substrate 10, the sealing substrate 40 and the resin sheet 30 in step shown in FIG. 2(C) into individual organic EL display panels. For such separation, the glass may be cut using laser beams, may be cut mechanically by dicing, or may be broken by scribing. In FIG. 2(D), the laminated body is cut such that a size of the element substrate and a size of the sealing substrate 40 are larger than a size of the resin sheet 30.

FIG. 2(E) shows a state in which an organic seal 50 is formed on a side portion of the resin sheet 30 and between the sealing substrate 40 and the element substrate using a so-called under-filling method after separating the laminated body into the individual organic EL display panels. The organic seal 50 is made of an acrylic resin having viscosity of approximately 70 Poise to 200 Poise. As shown in FIG. 2(E), the acrylic resin may preferably be of a type which exhibits excellent wettability with the element substrate or the glass substrate. That is, as shown in FIG. 2(F), a contact angle θ between the element substrate and the organic seal 50 is preferably set to less than 90 degrees. Due to such constitution, a sealing width of the organic seal 50 can be substantially increased. The same goes for sealing of the organic seal 50 on a sealing substrate 40 side. After forming the organic seal 50 by an under-filling method, ultraviolet rays are radiated to the organic seal 50 for curing the organic seal 50.

Here, by forming the resin sheet 30 using a resin sheet having moisture absorbing property, the resin sheet 30 also functions as a desiccant and hence, a lifetime of the organic EL layer can be more effectively prolonged. With respect to series of steps ranging from step shown in FIG. 2(A) to step shown in FIG. 2(F), the series of steps ranging from step shown in FIG. 2(B) to step shown in FIG. 2(E) may preferably be performed in a nitrogen atmosphere in which a dew point is set to −50° C. or less, preferably, −70° C. or less, and oxygen density is set to 100 ppm, preferably, 1 ppm or less. Particularly, when the resin sheet 30 is formed using a material having water absorbing property, the above-mentioned condition is especially important. Further, it is necessary to perform step shown in FIG. 2(B) to and step shown in FIG. 2(C) in a reduced pressure atmosphere for preventing the entrainment of bubbles into the resin sheet 30 at the time of performing the lamination.

To explain further advantageous effects of the present invention, a step of forming a pattern of the sealing agent which requires a control of the sealing width and a gap between the element substrate 10 and the sealing substrate 40 becomes unnecessary. Further, the adjustment of an internal pressure in performing the step of adhering the element substrate 10 and the sealing substrate 40 to each other also becomes unnecessary. Accordingly, the sealing processing can be simplified and, at the same time, a yield rate of the sealing step can be enhanced.

To explain still another advantageous effect of the present invention, the step of filling the sealing agent can be performed in a state that the organic EL display panels are individually separated from each other and hence, following advantageous effects can be acquired. That is, when a defect of the element substrate is clearly found, a defective device or a defective sealing glass can be selected in the step of filling the sealing agent and hence, the step of filling the sealing agent into a defective panel can be omitted. Further, this leads to the reduction of man-hours necessary for a lighting test of the organic EL display panel which is performed after filling the sealing agent. Further, with respect to a size of a facility for filling the sealing agent, it is sufficient to prepare an easy-to-use and small-sized facility for filling the sealing agent. Accordingly, a facility cost can be suppressed low and, at the same time, it is possible to provide a sealing process which can cope with variable-lot-in-large-kind production.

As has been explained heretofore, in this embodiment, the organic EL layer is covered with the resin sheet 30 and the organic seal 50 in a duplicated manner and hence, it is possible to acquire a high moisture prevention effect. Accordingly, the organic EL display device which possesses an excellent lifetime characteristic can be realized. Further, the manufacturing process can be simplified. Still further, the facility can be also simplified and hence, a manufacturing cost of the organic EL display device can be lowered.

### Embodiment 2

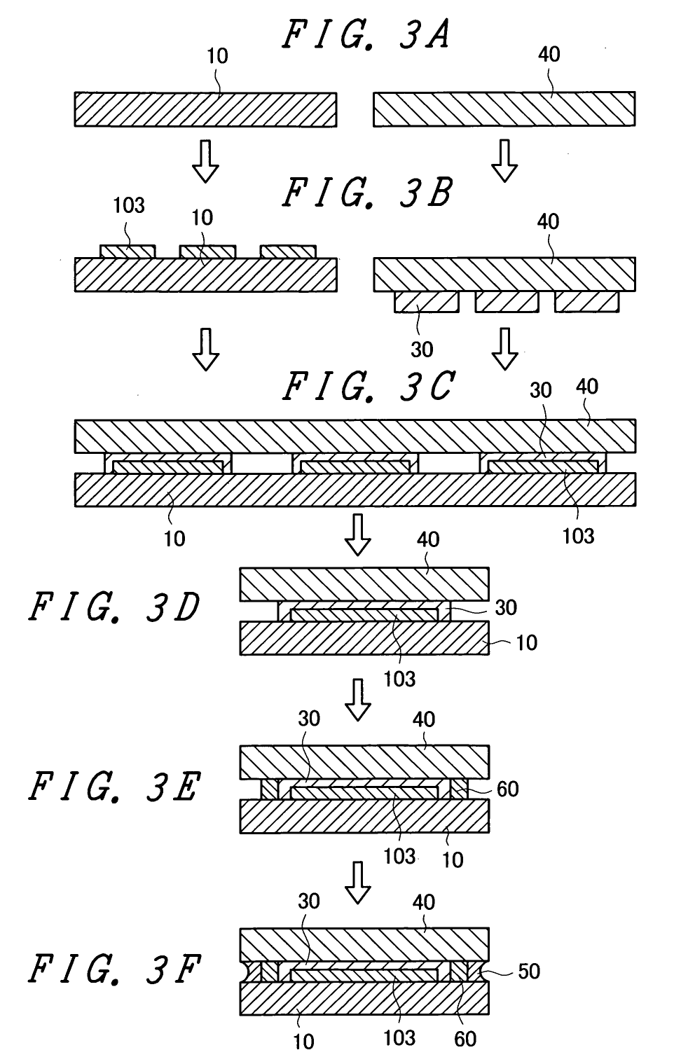

FIG. 3(A) to FIG. 3(F) are views showing manufacturing steps of a second embodiment of the present invention. An organic EL display device which is manufactured in the second embodiment can, in addition to the advantageous effects acquired by the first embodiment, further improve the sealing effect by performing sealing using an inorganic seal 60. The constitution of this embodiment is shown in FIG. 3(E) and FIG. 3(F). A cross section of a display region of the organic EL display device of this embodiment is substantially equal to the cross section of the organic EL display device shown in FIG. 1.

Among the constitutions of this embodiment 2 shown in FIG. 3(A) to FIG. 3(F), the constitutions shown FIG. 3(A) to FIG. 3(D) are substantially equal to the constitutions of the embodiment 1 shown FIG. 2(A) to FIG. 2(D). As shown in FIG. 3(E), the inorganic seal 60 is formed on a side surface of a resin sheet 30 between an element substrate and a sealing substrate 40. The inorganic seal 60 is provided for protecting an organic EL layer from moisture. As a material of the inorganic seal 60, silicon oxide, silicon nitride, aluminum oxide, titanium oxide, zirconium oxide, magnesium oxide or the like can be used. Out of these materials, silicon oxide, silicon nitride, and aluminum oxide exhibit a particularly large moisture prevention effect.

While the inorganic seal 60 made of an alumina-based material, the inorganic seal 60 made of a silicon-based material or the like has a function of blocking the intrusion of moisture, the inorganic seal 60 made of magnesium oxide can prevent the intrusion of moisture into the inside of the organic EL display device by absorbing the intruded moisture. These inorganic seals 60 can be formed by an atmospheric CVD method. In the atmospheric CVD method, a nozzle is inserted between the element substrate and the sealing substrate 40 and the inorganic material is applied to a side portion of the resin sheet 30 by coating. The inorganic seal 60 can also acquire a moisture prevention effect with a film thickness of approximately 0.1 μm. Further, aerosol or the like may be also used as a material of the inorganic seal 60.

After forming the inorganic seal 60, as shown in FIG. 3(F), in the same manner as the embodiment 1, the organic seal 50 is filled in a gap defined between the element substrate and the sealing substrate 40. A material of the organic seal 50, a method for applying the organic seal 50 and the like by coating are substantially equal to the material of the organic seal 50, the method for applying the organic seal 50 and the like which are explained in conjunction with the embodiment 1.

Further, also in this embodiment, with the use of the resin sheet 30 having the moisture absorbing property as a resin sheet, the resin sheet 30 also functions as a desiccant and hence, a lifetime of the organic EL layer can be more effectively prolonged. In this embodiment, the resin sheet 30 is arranged inside the inorganic seal 60 and hence, an amount of moisture which intrudes into the resin sheet 30 is reduced compared to a case explained in the embodiment 1. Accordingly, an advantageous effect which is acquired by imparting the moisture absorbing property to the resin sheet 30 can be further increased. Here, in steps ranging from step shown in FIG. 3(A) to step shown in FIG. 3(F), the step of forming the inorganic seal 60 shown in FIG. 3(E) may be also preferably performed in a nitrogen atmosphere in which a dew point is set to −50° C. or less, preferably, −70° C. or less, and an oxygen density is set to 100 ppm, preferably, 1 ppm or less.

Also in this embodiment, a step of forming a pattern of the sealing agent which requires a control of a sealing width and a gap between the element substrate and the sealing substrate 40 becomes unnecessary, and the adjustment of an internal pressure in performing the step of adhering the element substrate and the sealing substrate 40 to each other also becomes unnecessary. Accordingly, in the same manner as the embodiment 1, the sealing process can be simplified and, at the same time, a yield rate of the sealing step can be enhanced. As a still another advantageous effect of the present invention, in the same manner as the embodiment 1, there also exists an advantageous effect that the step of filling the sealing agent can be performed in a state that the organic EL display panels are individually separated from each other.

As has been explained heretofore, in this embodiment, the organic EL layer can be protected from moisture due to the three-layered structure consisting of the resin sheet 30, the inorganic seal 60 and the organic seal 50 and hence, this embodiment can further enhance the water prevention effect compared to a case explained in conjunction with the embodiment 1. Accordingly, the organic EL display device having an excellent lifetime characteristic can be realized. Further, a manufacturing process can be simplified and a facility can be also simplified and hence, a manufacturing cost of the organic EL display device can be reduced.

### Embodiment 3

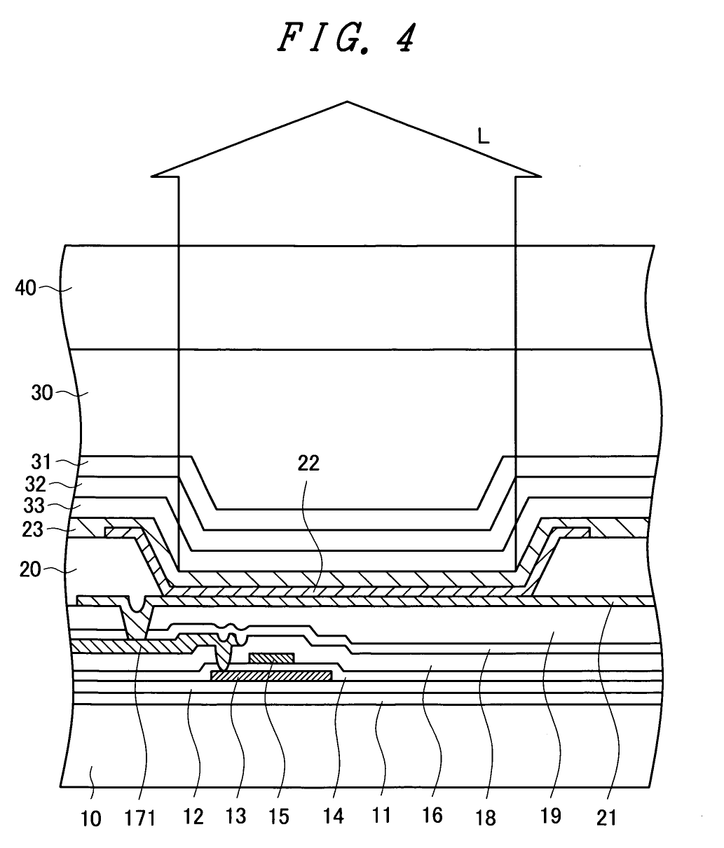

FIG. 4 is a cross-sectional view of a display part of an organic EL display device according to the embodiment 3 of the present invention. As shown in FIG. 4, the constitution of the embodiment 3 ranging from an element substrate to upper electrodes is substantially equal to the corresponding constitution of the embodiment 1 shown in FIG. 1. The technical feature of the constitution of this embodiment shown in FIG. 4 lies in that a three-layered inorganic protective film consisting of a first protective film 31, a second protective film 32 and a third protective film 33 is formed on the upper electrodes for protecting moisture. Due to the provision of the inorganic protective film, in laminating a resin sheet 30 to an element substrate 10, even when moisture intrudes into an interface between the resin sheet 30 and the upper electrode formed on an organic EL layer, it is possible to block the further intrusion of the moisture.

In FIG. 4, the first protective film 31 is formed of an SiNx film, an SiOx film or an SiNxOy film, for example, the second protective film 32 is formed of an MgO film, for example, and the third protective film 33 is formed of an SiNx film, an SiOx film or an SiNxOy film, for example. The first protective film 30 blocks moisture which intrudes below the resin sheet 30. The second protective film 32 is made of MgO which possesses moisture absorbing property. The MgO film plays a role of absorbing moisture which intrudes through pin holes or the like formed in the first protective film 31 thus playing a role of preventing the intrusion of moisture to the organic EL layers side. The third protective film 33 blocks moisture which cannot be absorbed by the second protective film 32 and passes the second protective film 32.

The resin sheet 30 is laminated to the first protective film 31. Before being laminated to the first protective film 31, the resin sheet 30 is laminated to the sealing substrate 40. A method of laminating the resin sheet 30 to the sealing substrate 40 is substantially equal to the method explained in conjunction with the embodiment 1. The resin sheet 30 which is laminated to the sealing substrate 40 is laminated to the upper electrode on the organic EL layer of the element substrate. This lamination method is also substantially equal to the lamination method explained in conjunction with the embodiment 1.

Thereafter, as shown in FIG. 2(E), the organic seal 50 is filled in a space formed around a side surface of the resin sheet 30 and between the element substrate and the sealing substrate 40 by an under-filling method explained in conjunction with the embodiment 1, and the organic seal 50 is cured by the radiation of ultraviolet rays. The under-filling method, a shape of the organic seal 50 and the like are substantially equal to the under-filling method, the shape of the organic seal 50 and the like which are explained in conjunction with the embodiment 1.

As another modification of this embodiment, as has been explained in conjunction with the embodiment 2, by sealing the side surface of the resin sheet 30 using the inorganic seal 60 before the side surface of the resin sheet 30 is sealed by the organic seal 50, the sealing effect can be further enhanced. Further, the method of forming the inorganic seal 60 is also substantially equal to the seal forming method explained in conjunction with the embodiment 2.

In this embodiment, the explanation has been made with respect to the case in which the three-layered protective film is used. However, the protective film is not limited to such a three-layered protective film and may be formed of a one-layered film or a two-layered film. When the protective film is formed of the one-layered film or the two-layered film, it is preferable to use a SiNx film, a SiOx film or a SiNxOy film. However, it is preferable to adopt the three-layered structure because the MgO film possesses moisture absorbing property and hence, by using the MgO film in a form that the MgO film is sandwiched between two films among the SiNx film, the SiOx film, the SiNxOy film and the like, it is possible to acquire a more effective moisture prevention effect.

As described above, according to this embodiment, by forming the protective film between the upper electrode formed on the organic EL layers and the resin sheet 30, it is possible to more surely protect the organic EL layers from moisture compared to cases explained in conjunction with the embodiment 1 or the embodiment 2. Further, also in this embodiment, the step of forming a pattern of the sealing agent which requires a control of a sealing width and a gap between the element substrate and the sealing substrate 40 becomes unnecessary, and the adjustment of an internal pressure in performing the step of adhering the element substrate and the sealing substrate 40 to each other also becomes unnecessary. Accordingly, in the same manner as the embodiment 1, the sealing process can be simplified and, at the same time, a yield rate of the sealing step can be enhanced. As a still another advantageous effect of the present invention, in the same manner as the embodiment 1, this embodiment can also acquire an advantageous effect that the step of filling the sealing agent can be performed in a state that the organic EL display panels are individually separated from each other.

In the above-mentioned embodiments, the explanation has been made with respect to the case in which the organic EL display device is the top-emission-type organic EL display device. However, the present invention is also applicable to a case in which the organic EL display device is a bottom-emission-type organic EL display device. There exists the following large difference between the top-emission type organic EL display device and the bottom-emission type organic EL display device. That is, the lower electrodes which sandwich the organic EL layer are made of a high-reflectance Al alloy or the like and the upper electrode is formed of the transparent conductive film such as an IZO film in the top-emission type organic EL display device, while a high-reflectance Al alloy or the like is used as the upper electrode and the transparent conductive film such as an IZO film is used as the lower electrode in the bottom-emission type organic EL display device.

Accordingly, the resin sheet 30 is laminated to the transparent conductive film such as an IZO film in the top-emission type organic EL display device, while the resin sheet 30 is laminated to the metal film made of an aluminum alloy or the like in the bottom-emission type organic EL display device. The lamination of the resin sheet 30 to the metal film can be performed by a method substantially equal to the method explained in conjunction with the embodiment 1. Accordingly, the present invention is also applicable to the bottom-emission type organic EL display device.

What is claimed is:

1. An organic EL display device comprising:
an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and
a sealing substrate which seals the display region, wherein
a resin sheet is sandwiched between the element substrate and the sealing substrate, and a space which is formed around a side surface of the resin sheet and between the element substrate and the sealing substrate is filled with an organic seal.

2. An organic EL display device according to claim 1, wherein the resin sheet is laminated to the sealing substrate, and the resin sheet is also laminated to the upper electrodes formed on the element substrate.

3. An organic EL display device according to claim 1, wherein the organic seal is cured by ultraviolet rays.

4. An organic EL display device according to claim 1, wherein a protective film is formed on the upper electrodes.

5. An organic EL display device according to claim 4, wherein the protective film is an inorganic film and contains any one of SiNx, SiOx and SiNxOy.

6. An organic EL display device according to claim 4, wherein the protective film is formed of a plurality of layers, and at least one layer out of the plurality of layers contains any one of SiNx, SiOx and SiNxOy.

7. An organic EL display device comprising:
an element substrate which includes a display region on which pixels each of which has an upper electrode, a lower electrode, and an organic EL layer sandwiched between the upper electrode and the lower electrode are formed in a matrix array and a terminal portion which supplies an electric current and a signal to the display region; and
a sealing substrate which seals the display region, wherein
a resin sheet is sandwiched between the element substrate and the sealing substrate, an inorganic seal is formed on a side surface of the resin sheet and between the element substrate and the sealing substrate, and an organic seal is formed outside the inorganic seal and between the element substrate and the sealing substrate.

8. An organic EL display device according to claim 7, wherein the inorganic seal contains any one of silicon oxide, silicon nitride, aluminum oxide, titanium oxide, zirconium oxide, and magnesium oxide.

9. An organic EL display device according to claim 7, wherein a protective film is formed on the upper electrodes.

10. An organic EL display device according to claim 7, wherein the protective film is an inorganic film and contains any one of SiNx, SiOx and SiNxOy.

11. An organic EL display device according to claim 7, wherein the protective film is formed of a plurality of layers, and at least one layer out of the plurality of layers contains any one of SiNx, SiOx and SiNxOy.

12. A manufacturing method of an organic EL display device which includes an element substrate having a display region on which pixels each of which has an upper electrode, a lower electrode, and an organic EL layer sandwiched between the upper electrode and the lower electrode are formed in a matrix array and a terminal portion which supplies an electric current and a signal to the display region, a sealing substrate which seals the display region, and a resin sheet which is sandwiched between the element substrate and the sealing substrate, wherein
the manufacturing method of an organic EL display device comprising the steps of:
adhering the resin sheet to a predetermined position of the sealing substrate;
adhering the resin sheet to the element substrate; and
filling an organic seal in a space which is formed around a side surface of the resin sheet and between the element substrate and the sealing substrate.

13. A manufacturing method of an organic EL display device according to claim 12, wherein the sealing substrate and the resin sheet are adhered to each other by lamination, and the resin sheet and the element substrate are adhered to each other by lamination.

14. A manufacturing method of an organic EL display device according to claim 12, wherein the organic seal is filled in the space which is formed between the element substrate and the sealing substrate by an under-filling method.

15. A manufacturing method of an organic EL display device which includes an element substrate having a display region on which pixels each of which has an upper electrode, a lower electrode, and an organic EL layer sandwiched between the upper electrode and the lower electrode are formed in a matrix array and a terminal portion which supplies an electric current and a signal to the display region, a sealing substrate which seals the display region, and a resin sheet which is sandwiched between the element substrate and the sealing substrate, wherein
the manufacturing method of an organic EL display device comprising the steps of:
adhering a mother element substrate on which a plurality of regions each including the display region and the terminal portion is formed and a mother sealing substrate to which a plurality of resin sheets is adhered corresponding to the display regions to each other;
separating a substrate formed by adhering the mother element substrate and the mother sealing substrate into individual organic EL display panels; and
applying an organic seal to a side surface of the resin sheet between the element substrate and the sealing substrate of the separated organic EL display panel by coating.

16. A manufacturing method of an organic EL display device according to claim 15, wherein the organic seal is applied to the side surface by an under-filling method.
